(19) United States
(12) Patent Application Publication
(10) Pub. No.: US 2025/0089473 A1
(43) Pub. Date: Mar. 13, 2025

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventors: Guoqiang YANG, Wuhan, Hubei (CN); Liliang GONG, Wuhan, Hubei (CN)

(73) Assignee: Wuhan China Star Optoelectronics Semiconductor Display Technology Co., Ltd., Wuhan, Hubei (CN)

(21) Appl. No.: 18/279,228

(22) PCT Filed: Jul. 20, 2023
(86) PCT No.: PCT/CN2023/108493

§ 371 Date: Aug. 29, 2023

(30) Foreign Application Priority Data
Jun. 15, 2023 (CN) 202310716512.7

(51) Int. Cl. H10K 59/124; H10K 59/80

(52) U.S. Cl. CPC H10K 59/124; H10K 59/8792

(57) ABSTRACT

A display panel and a display device are provided by the present application. A plurality of second pixels are electrically connected with pixel driving circuits located in a main display area. A pixel driving circuit layer corresponding to the light-transmitting display area is provided with a plurality of first grooves provided between the second pixels. The first grooves adjacent to different second pixels are communicated with each other. A distance from a surface of a first organic insulating sub-layer located at the first grooves away from a substrate to the substrate is less than a distance from a surface of the first organic insulating sub-layer located in the main display area away from the substrate to the substrate.

### TECHNICAL FIELD

The present application relates to a technical field of display, and in particular to a display panel and a display device.

### BACKGROUND

Imaging components are disposed corresponding to a light-transmitting display area of a display panel to realize an overall screen design. However, a pixel density of the light-transmitting display area is set too high, a light transmittance of a screen may be reduced, and a display effect of the screen is affected. The pixel density of the light-transmitting display area is reduced, which may affect the display effect of the screen. Therefore, when the light-transmitting display area and a main display area adopt a same pixel density design, the light transmittance of the light-transmitting display area is lower, which hinders a development of overall screen technology.

### SUMMARY

A display panel and a display device are provided by embodiments of the present application to improve a problem that a light transmittance of the light-transmitting display area is lower when a light-transmitting display area and a main display area adopt a same pixel density design.

The embodiments of the present application provide a display panel. The display panel includes a light-transmitting display area and a main display area adjacent to the light-transmitting display area, and a light transmittance of the light-transmitting display area is greater than a light transmittance of the main display area. The display panel includes a substrate, a pixel driving circuit layer, an organic insulating layer, and a light-emitting layer. The pixel driving circuit layer is located on the substrate and includes a plurality of pixel driving circuits arranged in the main display area. The organic insulating layer is located on the pixel driving circuit layer and includes a first organic insulating sub-layer and a second organic insulating sub-layer located on the first organic insulating sub-layer. The light-emitting layer is located on the organic insulating layer and includes a plurality of first pixels located in the main display area and a plurality of second pixels located in the light-transmitting display area, and the first pixels and the second pixels are electrically connected with the corresponding pixel driving circuits. The pixel driving circuit layer includes a plurality of first grooves in the light-transmitting display area and located between the second pixels, the first grooves adjacent to different second pixels are communicated with each other, the first organic insulating sub-layer fills the first grooves, and a first distance from a surface of the first organic insulating sub-layer located at the first grooves away from the substrate to the substrate is less than a second distance from a surface of the first organic insulating sub-layer located in the main display area away from the substrate to the substrate.

Alternatively, in some embodiments of the present application, the pixel driving circuit layer further includes a plurality of protrusions disposed in the light-transmitting display area and corresponding to the second pixels, one of the plurality of protrusions being surrounded by the first grooves. A third distance from a surface of the first organic insulating sub-layer located on the protrusions away from the substrate to the substrate is greater than the first distance from the surface of the first organic insulating sub-layer located at the first grooves away from the substrate to the substrate, and less than the second distance of the surface of the first organic insulating sub-layer located in the main display area away from the substrate to the substrate.

Alternatively, in some embodiments of the present application, the pixel driving circuit layer further includes a plurality of second grooves in the light-transmitting display area and corresponding to the second pixels, and the second grooves are communicated with the adjacent first grooves.

Alternatively, in some embodiments of the present application, a fourth distance from a surface of the first organic insulating sub-layer located at the second grooves away from the substrate to the substrate is equal to the first distance from the surface of the first organic insulating sub-layer located at the first grooves away from the substrate to the substrate.

Alternatively, in some embodiments of the present application, a depth of the first grooves is equal to a depth of the second grooves.

Alternatively, in some embodiments of the present application, the first organic insulating sub-layer includes third grooves in the light-transmitting display area and corresponding to the first grooves. A width of the third grooves is less than or equal to a width of the first grooves.

Alternatively, in some embodiments of the present application, a projection width of sidewalls of the third grooves on the substrate is less than or equal to a projection width of sidewalls of the first grooves on the substrate.

Alternatively, in some embodiments of the present application, each of the first grooves includes a plurality of sub-grooves stacked and communicated with each other. A width of the sub-grooves away from the substrate is greater than a width of the sub-grooves adjacent to the substrate.

Alternatively, in some embodiments of the present application, the plurality of the sub-grooves include a first sub-groove and a second sub-groove. The pixel driving circuit layer includes a buffer layer, a first gate insulating layer, a second gate insulating layer, and an interlayer dielectric layer. The buffer layer is located on the substrate, the first gate insulating layer is located on the buffer layer, the second gate insulating layer is located on the first gate insulating layer, and the interlayer dielectric layer located on the second gate insulating layer. A width of the first sub-groove formed on the buffer layer and the first gate insulating layer is less than a width of the second sub-groove formed on the second gate insulating layer and the interlayer dielectric layer.

Alternatively, in some embodiments of the present application, an included angle between a bottom surface of the second sub-groove and a sidewall of the second sub-groove is less than or equal to 115 degrees.

Alternatively, in some embodiments of the present application, the display panel further includes a light shielding layer located below the pixel driving circuit layer, the light shielding layer is provided with an opening corresponding to the first groove, and a width of the opening is greater than or equal to the width of the first sub-groove.

Alternatively, in some embodiments of the present application, the substrate includes a base substrate and a barrier layer thereon.

The present application further provides a display device including any one of the display panels mentioned above.

### Beneficial Effects

Compared with prior art, a display panel and a display device are provided by the present application, a plurality of second pixels of a light-emitting layer located in a light-transmitting display area are correspondingly electrically connected with pixel driving circuits located in a main display area, so that the whole light-transmitting display area has no pixel driving circuit. The pixel driving circuit layer is provided with a plurality of first grooves between the second pixels corresponding to the light-transmitting display area, the first grooves adjacent to different second pixels are communicated with each other, and the first organic insulating sub-layer of the organic insulating layer fills the first grooves, so that a first distance from a surface of the first organic insulating sub-layer located at the first grooves away from a substrate to the substrate is less than a second distance from a surface of the first organic insulating sub-layer located in the main display area away from the substrate to the substrate, so as to reduce an interface reflection, interference and the like of a part corresponding to the light-transmitting display area of the pixel driving circuit layer, which is conducive to improve a light transmittance of the light-transmitting display area and improve a problem of a lower light transmittance of the light-transmitting display area when the light-transmitting display area and the main display area adopt a same pixel density design. By providing a second organic insulating sub-layer on the first organic insulating sub-layer to provide a better flatness basis for the second pixels.

### BRIEF DESCRIPTION OF THE DRAWINGS

FIG. 1 is a structural schematic diagram of a main display area and a light-transmitting display area provided by embodiments of the present application.

FIG. 2A-FIG. 2D are structural schematic diagrams of a display panel provided by embodiments of the present application.

FIG. 3 is a structural schematic diagram of a boundary of an opening and a boundary of a groove provided by embodiments of the present application.

### DETAILED DESCRIPTION

In order to make a purpose, a technical solution, and effects of the present application clearer and more definite, the present application is further described in detail with reference to accompanying drawings and embodiments. It should be understood that the specific embodiments described herein are intended to be explanatory only and are not intended to be limiting.

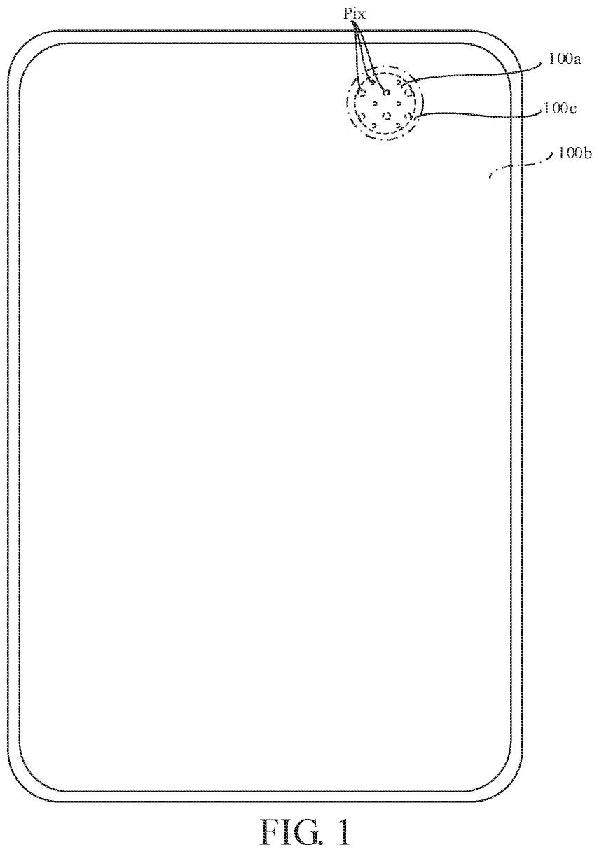

Specifically, specifically, FIG. 1 is a structural schematic diagram of a main display area and a light-transmitting display area provided by embodiments of the present application. The embodiments of the present application provide a display panel including a light-transmitting display area 100a and a main display area 100b adjacent to the light-transmitting display area 100a. A light transmittance of the light-transmitting display area 100a is greater than a light transmittance of the main display area 100b.

Alternatively, the main display area 100b is located at a periphery of the light-transmitting display area 100a. Alternatively, the main display area 100b is configured to realize a display function of the display panel. The light-transmitting display area 100a is configured to realize sensing functions while realizing the display function of the display panel. Alternatively, the sensing functions realized of the light-transmitting display area 100a include imaging, fingerprint identification, and the like by passing through sensing light.

Alternatively, the display panel includes light-sensing devices disposed corresponding to the light-transmitting display area 100a. Alternatively, the light-sensing devices include a camera, a light sensor, and the like.

Alternatively, the main display area 100b includes a transition display area 100c located at the periphery of the light-transmitting display area 100a. Alternatively, the transition display area 100c is configured to realize the display function of the display panel.

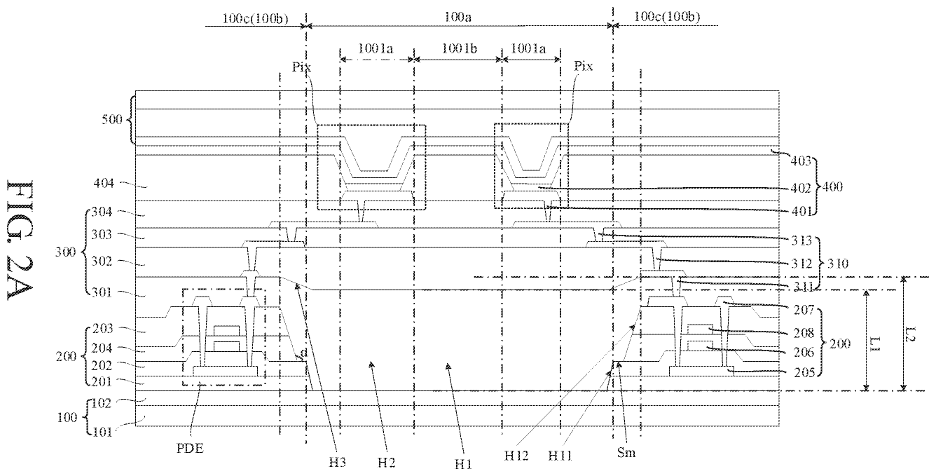

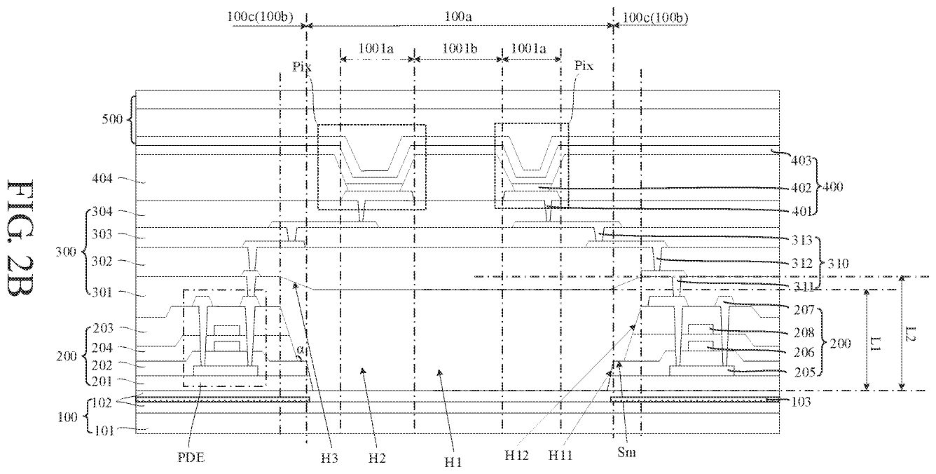

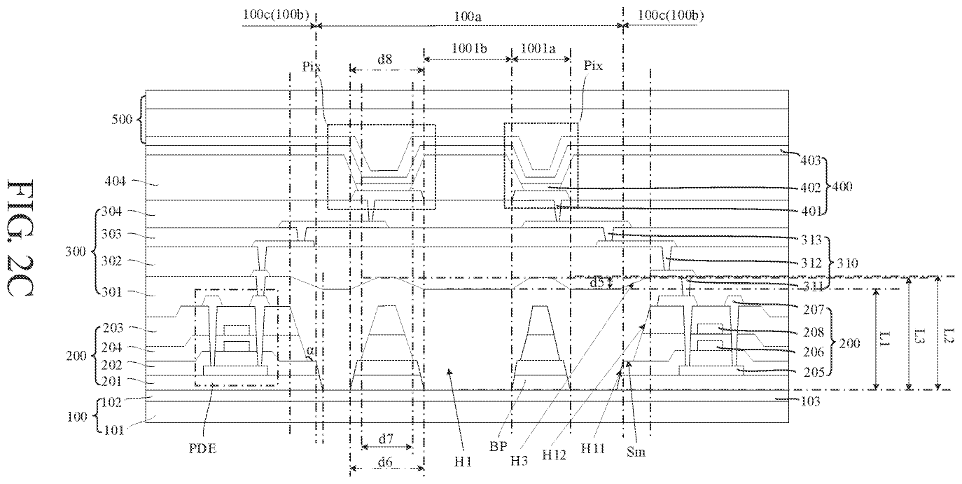

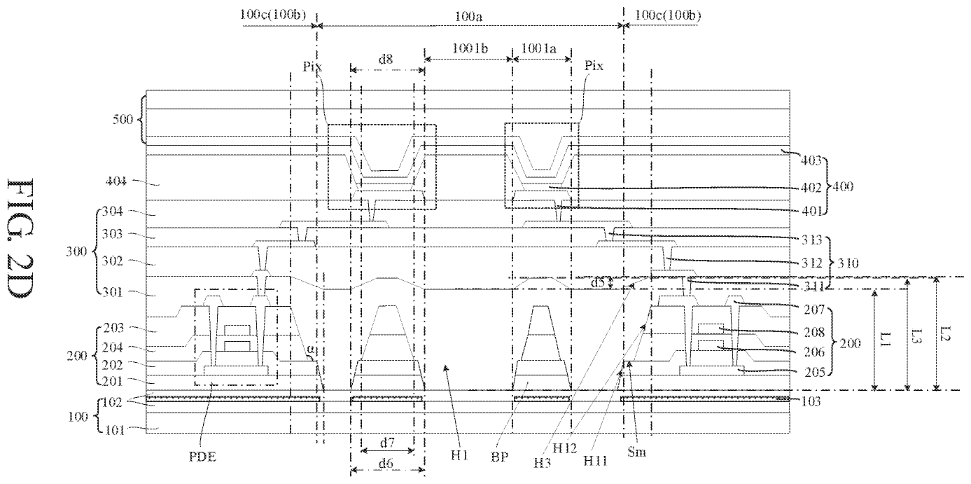

FIG. 2A-FIG. 2D are structural schematic diagrams of the display panel provided by embodiments of the present application.

The display panel includes a substrate 100, a pixel driving circuit layer 200, an organic insulating layer 300, and a light-emitting layer 400.

Alternatively, the substrate 100 includes a base substrate 101 and a barrier layer 102 thereon.

Alternatively, a manufacturing material of the base substrate 101 includes a flexible base substrate and a rigid base substrate. Alternatively, the base substrate 101 may be formed as a single layer or repeatedly stacked into a plurality of layers by processes such as coating, curing, and the like. Alternatively, the flexible base substrate includes polyimide or the like. Alternatively, the base substrate 101 may be a flexible base substrate formed by coating a polymeric material such as polyimide on a supporting base substrate and curing the polymeric material. Alternatively, the supporting base substrate includes glass, metal, ceramics, and the like. The polymeric material may be coated on the supporting base substrate by a coating process such as spin coating, slit coating, ink jet coating, and the like. The supporting base substrate may be removed in a subsequent process. Alternatively, the rigid base substrate includes glass, ceramics, and the like.

Alternatively, a manufacturing material of the barrier layer 102 includes various insulating materials (for example, silicon oxide, silicon nitride, or the like). Alternatively, the barrier layer 102 may be a single-layer or multi-layer structure. The barrier layer 102 may be configured to prevent impurities and moisture from penetrating into the light-emitting layer 400 from the base substrate 101.

Alternatively, the barrier layer 102 includes a first barrier layer and a second barrier layer located between the first barrier layer and the base substrate. The first barrier layer may be formed of SiOx or SiON, and the second barrier layer may be formed of SiNx or SiON.

The pixel driving circuit layer 200 is located on the substrate 100 and includes a plurality of inorganic insulating layers stacked and a plurality of pixel driving circuits PDE arranged in the main display area 100b.

Alternatively, the pixel driving circuits PDE that drive the second pixels Pix located in the light-transmitting display area 100a to emit light may be located in the transition display area 100c, and the pixel driving circuits PDE that drive the first pixels located in the main display area 100b to emit light is correspondingly located in the main display area 100b, so as to reduce interference of the pixel driving circuits PDE on the light transmittance of the light-transmitting display area 100a.

The pixel driving circuit layer 200 includes a plurality of first grooves H1 provided in the light-transmitting display area 100a and located between the second pixels Pix. The first grooves H1 adjacent to different second pixels Pix are communicated with each other.

Alternatively, the first grooves H1 exposes the barrier layer 102 to prevent impurities and moisture from penetrating into the light-emitting layer 400 from the base substrate 101 through the barrier layer 102.

Alternatively, the pixel driving circuit layer 200 includes a buffer layer 201, a first gate insulating layer 202, and an interlayer dielectric layer 203.

The buffer layer 201 is located on the substrate 100 to prevent the impurities and moisture from penetrating into the light-emitting layer 400 from the substrate 100. Alternatively, the buffer layer 201 may be a single-layer or multi-layer structure, and a manufacturing material of the buffer layer 201 includes a material such as silicon oxide or silicon nitride.

The first gate insulating layer 202 is located on the buffer layer 201. The first gate insulating layer 202 may be a single-layer or multi-layer structure. A manufacturing material of the first gate insulating layer 202 includes at least one of silicon nitride, silicon oxide, and the like.

The interlayer dielectric layer 203 is located on the first gate insulating layer 202. The interlayer dielectric layer 203 may be a single layer or a multi-layer structure. A preparation material of the interlayer dielectric layer 203 includes at least one of silicon nitride, silicon oxide, and the like.

Alternatively, at least parts other than the second pixels Pix of the buffer layer 201, the first gate insulating layer 202, and the interlayer dielectric layer 203 are provided with the first grooves H1 communicated with each other.

Alternatively, the pixel driving circuit layer 200 further includes a second gate insulating layer 204 located on the first gate insulating layer 202, and the interlayer dielectric layer 203 is located on the second gate insulating layer 204. The second gate insulating layer 204 may be a single-layer or multi-layer structure. A manufacturing material of the second gate insulating layer 204 includes at least one of silicon nitride, silicon oxide, and the like.

Alternatively, the buffer layer 201, the first gate insulating layer 202, the second gate insulating layer 204, and the interlayer dielectric layer 203 are provided with a plurality of the first grooves H1.

Alternatively, the pixel driving circuit layer 200 further includes an active layer 205, a first gate layer 206, and a source-drain layer 207.

The active layer 205 is located between the buffer layer 201 and the first gate insulating layer 202. Alternatively, the active layer 205 includes a silicon semiconductor material, an oxide semiconductor material, and the like. Alternatively, the silicon semiconductor material includes a polysilicon material.

The first gate layer 206 is located between the first gate insulating layer 202 and the second gate insulating layer 204, and the first gate layer 206 includes a gate electrode disposed corresponding to a channel area of the active layer 205. Alternatively, the first gate layer 206 may be a single-layer or multi-layer structure, and a manufacturing material of the first gate layer 206 includes Al, Ti, Mo, Cu, Ni, or alloys thereof, or a material having high corrosion resistance, etc.

The source-drain layer 207 is located on the interlayer dielectric layer 203 and includes a source electrode and a drain electrode electrically connected to a source area and a drain area of the active layer 205 respectively. Alternatively, the source-drain layer 207 may be a single-layer or multi-layer structure, and a manufacturing material of the source-drain layer 207 includes at least one of Al, Ti, Mo, Cu, Ni, or an alloy thereof, or a material having high anticorrosion performance, etc.

The gate electrode forms a control electrode of a transistor, the source electrode forms an input electrode of the transistor, and the drain electrode forms an output electrode of the transistor. The gate electrode, the source electrode, and the drain electrode form the transistor in the pixel driving circuits PDE with the active layer 205.

Alternatively, the first gate layer 206 further includes scanning lines, etc. The source-drain layer 207 further includes data lines, etc. The scanning lines and the data lines are electrically connected with the pixel driving circuits PDE, so that the pixel driving circuits PDE drive corresponding light-emitting devices to emit light according to scanning signals transmitted by the scanning lines and data signals transmitted by the data lines. The light-emitting devices are the first pixels or the second pixels.

Alternatively, the display panel further includes a second gate layer 208 and a signal connecting layer 310.

The second gate layer 208 is located between the second gate insulating layer 204 and the interlayer dielectric layer 203. The second gate layer 208 includes an electrode plate part disposed corresponding to the gate electrode, so that the gate electrode and the electrode plate part form two electrodes of a capacitance. Alternatively, the second gate layer 208 may be a single-layer or multi-layer structure, and a manufacturing material of the second gate layer 208 includes at least one of Al, Ti, Mo, Cu, Ni, or an alloy thereof, or a material having high corrosion resistance, etc.

The signal connecting layer 310 is located on the source-drain layer 207. The signal connecting layer 310 includes a plurality of signal connecting parts electrically connected with corresponding transistors. Alternatively, a manufacturing material of the signal connecting layer 310 includes at least one of Al, Ti, Mo, Cu, Ni, or an alloy thereof, or a material having high anticorrosive properties, etc. Alternatively, the manufacturing material of the signal connecting layer 310 includes a transparent conductive material to reduce an influence of the signal connecting layer 310 on the light transmittance of the light-transmitting display area 100a.

Continue to refer to FIG. 2A to FIG. 2D, the organic insulating layer 300 is located on the pixel driving circuit layer 200. The organic insulating layer 300 includes a first organic insulating sub-layer 301 and a second organic insulating sub-layer 302 located on the first organic insulating sub-layer 301. The first organic insulating sub-layer 301 fills the first grooves H1.

Alternatively, a first distance L1 from a surface of the first organic insulating sub-layer 301 located at the first groove H1 away from the substrate 100 to the substrate 100 is less than a second distance L2 from a surface of the first organic insulating sub-layer 301 located at the main display area 100b away from the substrate 100 to the substrate 100 (that is, L1 is less than L2), so that a top surface of a part of the first organic insulating sub-layer 301 correspondingly located within the first grooves H1 is lower than a top surface of a part of the first organic insulating sub-layer 301 correspondingly located within the main display area 100b. Alternatively, a top surface of a part of the second organic insulating sub-layer 302 corresponding to the first grooves H1 is flush with a top surface of a part of the second organic insulating sub-layer 302 corresponding to the main display area 100b, so as to provide a better flatness basis for the second pixels Pix included in the light-emitting layer 400.

Continue to refer to FIG. 2A to FIG. 2D, the light-emitting layer 400 is located on the organic insulating layer 300. The light-emitting layer 400 includes a plurality of first pixels located in the main display area 100b and a plurality of second pixels Pix located in the light transmitting display area 100a. The first pixels and the second pixels Pix are electrically connected to the corresponding pixel driving circuits PDE. By electrically connecting the plurality of second pixels Pix to the pixel driving circuits PDE located in the main display area 100b, so that there is no pixel driving circuit PDE in the entire light-transmitting display area 100a, the inorganic insulating layer (that is, the buffer layer 201, the first gate insulating layer 202, the second gate insulating layer 204, and the interlayer dielectric layer 203) corresponding to the entire light-transmitting display area 100a may be removed to form the first grooves H1, when the light transmittance of the light-transmitting display area 100a is increased. By providing the organic insulating layer 300 in the first grooves H1, the effects of interface reflection, interference, and the like in parts of the buffer layer 201, the gate insulating layer, and the interlayer dielectric layer 203 included in the pixel driving circuit layer 200 corresponding to the light-transmitting display area 100a are reduced, thereby improving the light transmittance of the light-transmitting display area 100a and improving a problem that the light transmittance of the light-transmitting display area 100a is lower when the light-transmitting display area 100a and the main display area 100b adopt a same pixel density design.

Alternatively, a refractive index of the first organic insulating sub-layer 301 may be less than or equal to 1.6, and an extinction coefficient of about 0, so that the first organic insulating sub-layer 301 has better light transmittance. Alternatively, the refractive index of the first organic insulating sub-layer 301 may be equal to 1.6, 1.5, 1.4, 1.3, 1.2, 1.1, 1, etc.

Alternatively, in per unit area, a density of the second pixels Pix located in the light-transmitting display area 100a and a density of the first pixels located in the main display area 100b are same.

Alternatively, the second pixels Pix and the first pixels include organic light-emitting diodes, sub-millimeter light-emitting diodes, micro light-emitting diodes, etc.

Alternatively, the light-emitting layer 400 is electrically connected to the corresponding pixel driving circuits PDE through the signal connecting layer 310.

Alternatively, the signal connecting layer 310 includes a first connecting layer 311 located on the first organic insulating sub-layer 301. The first connecting layer 311 includes a plurality of first connecting parts. Each of the first connecting parts is electrically connected with the corresponding pixel driving circuits PDE through a via hole penetrating the first organic insulating sub-layer 301.

Alternatively, the signal connecting layer 310 further includes a second connecting layer 312 electrically connected between the second pixels Pix and the first connecting layer 311, or between the first pixels and the first connecting layer 311.

Alternatively, the first connecting layer 311 is located between the first organic insulating sub-layer 301 and the second organic insulating sub-layer 302. The second connecting layer 312 is located on the second organic insulating sub-layer 302. The second connecting layer 312 includes a plurality of second connecting parts. Each of the second connecting parts is electrically connected with the corresponding first connecting parts through a via hole penetrating the second organic insulating sub-layer 302.

Alternatively, in order to reduce a segment difference from a surface of the second organic insulating sub-layer 302 to make the surface of the second organic insulating sub-layer 302 have better flatness, the second organic insulating sub-layer 302 is manufactured by a two-time coating process to reduce a probability of the occurrence of fracture or short circuits of wirings located on the second organic insulating sub-layer 302 and provide better flatness for a first electrode layer 401 in the light-emitting layer 400. The first electrode layer 401 may be an anode layer or a cathode layer.

Alternatively, the signal connecting layer 310 further includes a third connecting layer 313 electrically connected between the second pixels Pix and the second connecting layer 312, or between the first pixels and the second connecting layer 312.

Alternatively, the organic insulating layer 300 further includes a third organic insulating sub-layer 303 located on the second organic insulating sub-layer 302. The second connecting layer 312 is located between the second organic insulating sub-layer 302 and the third organic insulating sub-layer 303. The third connecting layer 313 is located on the third organic insulating sub-layer 303. The third connecting layer 313 includes a plurality of third connecting parts. Each of the third connecting parts is electrically connected with the corresponding third connecting parts through a via hole through the third organic insulating sub-layer 303.

Alternatively, a manufacturing material of the third organic insulating sub-layer 303 includes silicon oxide to block gas release to the light-emitting layer 400 in the second organic insulating sub-layer 302, the first organic insulating sub-layer 301, the barrier layer 102, and the substrate 101 below the third organic insulator layer 303.

Alternatively, the plurality of first connecting parts are located in the transition display area 100c to avoid problems such as fracture of the plurality of first connecting parts caused by a segment difference of the first organic insulating sub-layer 301 at the corresponding first grooves H1, thereby reducing a probability of electrical connection failures between the second pixels Pix located in the light-transmitting display area 100a and the corresponding pixel driving circuits PDE, which leads to a display failure of the display panel.

Alternatively, the plurality of second connecting parts are located in the transition display area 100c, or the plurality of second connecting parts extend from the transition display area 100c to the light-transmitting display area 100a, so that the second pixels Pix located in the light-transmitting display area 100a and the corresponding pixel driving circuits PDE are electrically connected.

Alternatively, the plurality of third connecting parts are located in the transition display area 100c, or the plurality of third connecting parts extend from the transition display area 100c to the light-transmitting display area 100a, so that the second pixels Pix located in the light-transmitting display area 100a and the corresponding pixel driving circuits PDE are electrically connected.

Alternatively, the organic insulating layer 300 further includes a fourth organic insulating sub-layer 304 located on the third organic insulating sub-layer 303 and the third connecting layer 313. The first electrode layer 401 of the light-emitting layer 400 includes a plurality of first electrodes, and each of the first electrodes is electrically connected with a corresponding signal connecting part through a via hole penetrating the fourth organic insulating sub-layer 304. The first electrodes are an anode or a cathode of the second pixels Pix or the first pixels.

Alternatively, the first electrode layer 401 is the anode layer, and the first electrodes are the anode.

Continue to refer to FIG. 2A to FIG. 2B, the pixel driving circuit layer 200 further includes a plurality of second grooves H2 provided in the light-transmitting display area 100a and corresponding to the second pixels Pix, and the second grooves H2 is communicated with the adjacent first grooves H1.

Alternatively, a fourth distance from a surface of the first organic insulating sub-layer 301 located at the second grooves H2 away from the substrate 100 to the substrate 100 is equal to the first distance L1 of the surface of the first organic insulating sub-layer 301 located at the first grooves H1 away from the substrate 100 to the substrate 100, so that a part of the first organic insulating sub-layer 301 corresponding to the second pixels Pix is flush with a part between the corresponding second pixels Pix.

Alternatively, a depth of the first grooves H1 is equal to a depth of the second grooves H2, so that the first grooves H1 and the second grooves H2 are manufactured simultaneously.

Alternatively, continue to refer to FIG. 2C to FIG. 2D, the light-transmitting display area 100a includes a plurality of display sub-areas 1001a and light-transmitting sub-areas 1001b located between the plurality of display sub-areas 1001a. The plurality of the second pixels Pix are located corresponding to the plurality of the display sub-areas 1001a. The first grooves H1 are provided corresponding to the light-transmission sub-areas 1001b.

The pixel driving circuit layer 200 further includes a plurality of protrusions BP disposed in the light-transmitting display area 100a and corresponding to the second pixels Pix. The protrusions BP are surrounded by the first grooves H1. A third distance L3 from a surface of the first organic insulating sub-layer 301 located on the protrusions BP away from the substrate 100 to the substrate 100 is greater than the first distance L1 from the surface of the first organic insulating sub-layer 301 located at the first grooves H1 away from the substrate 100 to the substrate 100, and less than the second distance L2 of the surface of the first organic insulating sub-layer 301 located in the main display area 100b away from the substrate 100 to the substrate 100 (that is, L1 is less than L2, and L2 is less than or equal to L3).

Alternatively, the protrusions BP includes a first sub-protrusion and a second sub-protrusion. The buffer layer 201 and the first gate insulating layer 202 are provided with the first sub-protrusion corresponding to the display sub-areas 1001a. The second gate insulating layer 204 and the interlayer dielectric layer 203 are provided with the second sub-protrusion corresponding to the display sub-areas 1001a. An orthographic projection of the first sub-protrusion on the substrate 100 has an eighth boundary (as d6 in FIG. 2C-FIG. 2D is a size defined by the eighth boundary). An orthographic projection of the second sub-protrusion on the substrate 100 has a ninth boundary (as d7 in FIG. 2C-FIG. 2D is a size defined by the ninth boundary). The ninth boundary is located within the eighth boundary to provide better support and flattening performance for the second pixels Pix through the protrusions BP.

Alternatively, each of the second pixels Pix includes a first electrode on the organic insulating layer 300. An orthographic projection of the first electrode on the substrate 100 has a tenth boundary (as d8 in FIG. 2C-FIG. 2D is a size defined by the tenth boundary). An orthographic projection of the protrusions BP on the substrate 100 is located within the orthographic projection of the first electrode on the substrate 100, so as to reduce the influence of the pixel driving circuit layer 200 on the light-transmittance of the light-transmitting display area 100a. The orthographic projection of the protrusions BP on the substrate 100 is within the orthographic projection of the first electrode on the substrate 100, including that the tenth boundary overlaps the eighth boundary, or the tenth boundary is outside the eighth boundary.

Compared with a design of FIG. 2A-FIG. 2B, the pixel driving circuit layer 200 is provided with the first grooves H1 merely corresponding to the light-transmission sub-areas 1001b, so that a size of the first grooves H1 is smaller. When the first organic insulating sub-layer 301 fills the first grooves H1, a segment difference between a top surface of the first organic insulating sub-layer 301 corresponding to the first grooves H1 and a top surface of the first organic insulating sub-layer 301 corresponding to the main display area 100b and the transition display area 100c is smaller (as shown by d5 in FIG. 2C-FIG. 2D), which is beneficial to improve a flatness of the surface of the second organic insulating sub-layer 302, thereby a probability of wire breakage in the signal connecting layer 310 may be reduced to a greater extent, and a flatness of the first electrode located in the light-transmitting display area 100a may be improved.

Continue to refer to FIG. 2A to FIG. 2D, since the first distance L1 is less than the second distance L2, the first organic insulating sub-layer 301 includes third grooves H3 provided in the light-transmitting display area 100a and corresponding to the first grooves H1. Alternatively, a width of the third grooves H3 is less than or equal to a width of the first groove H1, so that the organic insulating sub-layers located on the first organic insulating sub-layer 301 have better flatness, after the first grooves H1 are filled by the first organic insulating sub-layer 301 (that is, by increasing a number of film layers to be filled (for example, the third grooves H3 included in the first planarization layer 201 also needs to be filled), so as to obtain a flatter surface after multiple times of filling).

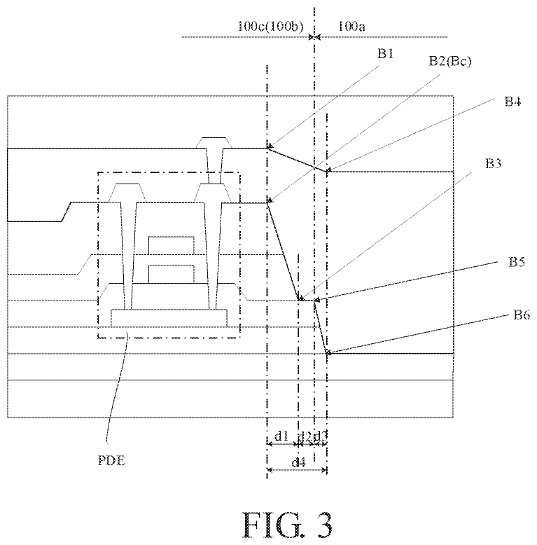

Alternatively, FIG. 3 is a structural schematic diagram of a boundary of an opening and a boundary of a groove provided by embodiments of the present application. A projection width of sidewalls of the third grooves H3 on the substrate 100 is less than or equal to a projection width of sidewalls of the first grooves H1 on the substrate 100. Alternatively, the projection width of the sidewalls of the third grooves H3 on the substrate 100 is equal to the projection width of the sidewalls of the first grooves H1 on the substrate 100, so as to reduce a probability of a dispersion problem of light at interlaced positions of the third grooves H3 and the first grooves H1.

Alternatively, the orthographic projection of the sidewalls of the third grooves H3 on the substrate 100 has a first boundary B1. The orthographic projection of the sidewalls of the first grooves H1 on the substrate 100 has a second boundary B2. The first boundary B1 is overlapped with the second boundary B2, so as to reduce the probability of the dispersion problem of light at the interlaced positions of the third grooves H3 and the first grooves H1.

It may be understood that the first boundary B1 and the second boundary B2 may not be completely overlapped in existing manufacturing methods due to limitations of process accuracy, process technology, and other factors. Therefore, the overlap of the first boundary B1 and the second boundary B2 referred to in the present application should further include the case where there is a spacing error between the first boundary B1 and the second boundary B2 due to the influence of process accuracy, process technology, and other factors.

Alternatively, continue to refer to FIG. 2A to FIG. 2D, in a thickness direction of the display panel, the first grooves H1 include a plurality of sub-grooves arranged stacked and communicated with each other. The larger the number of the sub-grooves, the more favorable it is to obtain a flatter surface of the first organic insulating sub-layer 301. However, the larger the number of the sub-grooves, the more the number of step surfaces formed between the sub-grooves will further increase, and the greater the number of step surfaces, the greater the probability of light scattering on the step surfaces. Therefore, in order to balance both flatness and optical performance, the number of step surfaces Sm between at least two adjacent sub-grooves in the thickness direction of the display panel is less than or equal to 2, so as to give consideration to both flatness and optical performance of the display panel.

Alternatively, the number of the step surfaces Sm may be 0, 1, or 2.

Alternatively, when the number of the step surfaces Sm is 0, sizes of the plurality of sub-grooves may be gradually increased or kept unchanged in a direction from the buffer layer 201 to the interlayer dielectric layer 203.

Alternatively, continue to refer to FIG. 2A to FIG. 2D, the buffer layer 201 and the first gate insulating layer 202 are provided with a first sub-groove H11 corresponding to the light-transmitting display area 100a (that is, a sidewall of the buffer layer 201 and a sidewall of the first gate insulating layer 202 corresponding to the light-transmitting display area 100a surround to form the first sub-groove H11). The second gate insulating layer 204 and the interlayer dielectric layer 203 are provided with a second sub-groove H12 corresponding to the light-transmitting display area 100a (that is, a sidewall of the second gate insulating layer 204 and a sidewall of the interlayer dielectric layer 203 corresponding to the light-transmitting display area 100a surround to form the second sub-groove H12). A width of the first sub-groove H11 is less than a width of the second sub-groove H12, so that the orthographic projection of the first sub-groove H11 on the substrate 100 is located within the orthographic projection of the second sub-groove H12 on the substrate 100, and the number of the step surfaces Sm is 1 or 0, thereby balancing both flatness and optical performance.

Alternatively, in the display panels shown in FIG. 2A to FIG. 2B, when the top surfaces of the plurality of the first grooves H1 and the top surfaces of the plurality of the second grooves H2 are flush, the plurality of the first grooves H1 and the plurality of the second grooves H2 may have a common boundary (as shown by Bc in FIG. 3).

Alternatively, in the display panels shown in FIG. 2C to FIG. 2D, when the display panels do not include the second grooves H2, each of the first grooves H1 corresponds to a first boundary B1. Accordingly, each of the first grooves H1 may correspondingly include the first sub-groove H11 and the second sub-groove H12.

Alternatively, continue to refer to FIG. 3, the orthographic projection of the second sub-groove H12 on the substrate 100 has a second boundary B2 and a third boundary B3. The orthographic projection of a bottom surface of the third groove H3 on the substrate 100 has a fourth boundary B4. The orthographic projection of the first sub-groove H11 on the substrate 100 has a fifth boundary B5 and a sixth boundary B6. In the display panels shown in FIG. 2A to FIG. 2B, the fourth boundary B4 is located within the boundary Bc, the third boundary B3 is located within the boundary Bc, the fifth boundary B5 is located within the boundary Bc, the sixth boundary B6 is located within the fifth boundary B5, and the fourth boundary B4 is overlapped with the sixth boundary B6, so as to reduce the probability of light scattering problems occurring at the intersection of the first sub-groove H11, the second sub-groove H12, and the third groove H3. In the display panels shown in f FIG. 2C to FIG. 2D, the fourth boundary B4 is located within the first boundary B1, the third boundary B3 is located within the second boundary B2, the fifth boundary B5 is located within the second boundary B2, and the sixth boundary B6 is located within the fifth boundary B5, and the fourth boundary B4 is overlapped with the sixth boundary B6, so as to reduce the probability of light scattering problems occurring at the intersection of the first sub-groove H11, the second sub-groove H12, and the third groove H3.

Alternatively, a first spacing distance d1 is between the second boundary B2 and the third boundary B3, or between the boundary Bc and the third boundary B3. A second spacing distance d2 is between the third boundary B3 and the fifth boundary B5. A third spacing distance d3 is between the fifth boundary B5 and the sixth boundary B6. The spacing distance d4 between the first boundary B1 and the fourth boundary B4 is equal to a sum of the first distance d1, the second distance d2, and the third distance d3 (that is. d4 is equal to a sum of d1, d2, and d3).

Alternatively, the second spacing distance d2 is less than or equal to 0.3 microns, and the third spacing distance d3 is less than or equal to 0.8 microns, so as to reduce the scattering of light at sides of the first sub-groove H11 and sides of the second sub-groove H12.

Alternatively, the second spacing distance d2 is equal to 0.3 microns, 0.25 microns, 0.21 microns, 0.2 microns, 0.18 microns, 0.15 microns, 0.1 microns, 0.05 microns, or 0 microns. Alternatively, the third spacing distance d3 is equal to 0.8 microns, 0.75 microns, 0.7 microns, 0.65 microns, 0.6 microns, 0.55 microns, 0.5 microns, 0.45 microns, 0.4 microns, 0.35 microns, 0.3 microns, 0.25 microns, 0.2 microns, 0.15 microns, 0.1 microns, or 0 microns.

It may be understood that in the existing manufacturing methods, the fourth boundary B4 and the sixth boundary B6 may not be completely overlapped when prepared due to the limitations of process accuracy, process technology, and other factors. Therefore, the overlap of the fourth boundary B4 and the sixth boundary B6 referred to in this application should also include the case where there is a spacing error between the fourth boundary B4 and the sixth boundary B6 due to the influence of process accuracy, process technology, and other factors.

Alternatively, in the display panels shown in FIG. 2A to FIG. 2B, the fifth boundary B5 may be coincided with a boundary of the light-transmitting display area 100a, or the sixth boundary B6 may be coincided with the boundary of the light-transmitting display area 100a, so as to ensure that the light transmittance of the entire light-transmitting display area 100a is improved. Alternatively, the first boundary B1, the boundary Bc, and the third boundary B3 are located within the transition display area 100c, so as to reduce the influence of the first boundary B1, the boundary Bc, and the third boundary B3 on the light transmittance of the light-transmitting display area 100a.

Alternatively, continue to refer to FIG. 2A to FIG. 2D, an included angle between the bottom surface of the second sub-groove H12 and the sidewall of the second sub-groove is less than or equal to 115 degrees (that is, the step surface Sm between the first sub-groove H11 and the second sub-groove H12 has an included angle α between the step surface Sm and the side wall of the second sub-groove H12, and a complementary angle of the included angle α is greater than or equal to 65 degrees, so that a side length of the second sub-groove H12 is smaller, thereby reducing light scattering at the side of the second sub-groove H12.

Alternatively, the complementary angle of the included angle α is equal to 65 degrees, 66 degrees, 67 degrees, 68 degrees, 69 degrees, 70 degrees, 71 degrees, 72 degrees, 73 degrees, 74 degrees, 75 degrees, 76 degrees, 77 degrees, 78 degrees, 79 degrees, 80 degrees, 81 degrees, 82 degrees, 83 degrees, 84 degrees, 85 degrees, 86 degrees, 87 degrees, 88 degrees, 89 degrees, or 90 degrees.

Alternatively, an included angle between a bottom surface of the first sub-groove H11 and a sidewall of the first sub-groove H11 is less than or equal to 115 degrees, so that a length of a side of the first sub-groove H11 is smaller, thereby reducing the scattering of light at the side of the first sub-groove H11.

Alternatively, continue to refer to FIG. 2B to FIG. 2D, the display panel further includes a light shielding layer 103 located below the pixel driving circuit layer 200. The light shielding layer 103 is provided with an opening corresponding to the first groove H1, and a width of the opening is greater than or equal to the width of the first sub-groove H11.

Alternatively, an orthographic projection of the opening on the substrate 100 has a seventh boundary between the sixth boundary B6 and the fifth boundary B5, so as to prevent the light transmittance of the light-transmitting display area 100a from being affected by the light-shielding layer while protecting the active layer 205 from being irradiated by light.

Alternatively, continue to refer to FIG. 2A to FIG. 2D, the light-emitting layer 400 further includes a light-emitting material layer 402 and a second electrode layer 403. The display panel includes a pixel definition layer 404, an encapsulation layer 500, and the like. The pixel definition layer 404 is located on the first electrode layer 401. The pixel definition layer 404 is provided with a pixel definition area corresponding to the first electrode, the light-emitting material layer 402 is located in the pixel definition area. The second electrode layer 403 is located on the light-emitting material layer 402. The encapsulation layer 500 is located on the second electrode layer 403.

After the pixel driving circuit layer 200 is provided with the first groove H1 corresponding to the light-transmitting display area 100a, and the first groove H1 is filled with a highly transparent organic material, inventors of the present application verifies that the light-transmittance of the display panel may be improved by about 15% (that is, the light transmittance of the display panel is improved from 63% to 78%). A camera is used as the light sensing element for verification, and the verification results show that the camera disposed corresponding to the light-transmitting display area 100a takes pictures more clearly and has richer details in a dark environment. Therefore, the light-transmittance of the light-transmitting display area 100a may be improved in the present application, thereby optimizing the imaging effect.

The present application further provides a display device including any one of the display panels mentioned above. It may be understood that the display device includes a movable display device (such as a notebook computer, a mobile phone, etc.), a fixed terminal (such as a desktop computer, a television, etc.), a measuring device (such as a sports bracelet, a thermometer, etc.), etc.

The principle and implementations of the present application are described in this specification by using specific examples. The description about the foregoing embodiments is merely provided to help understand the method and core ideas of the present application. In addition, persons of ordinary skill in the art can make modifications in terms of the specific implementations and application scopes according to the ideas of the present application. Therefore, the content of this specification shall not be construed as a limit to the present application.

1. A display panel, comprising a light-transmitting display area and a main display area adjacent to the light-transmitting display area, wherein a light transmittance of the light-transmitting display area is greater than a light transmittance of the main display area, and the display panel comprises:
a substrate;
a pixel driving circuit layer, located on the substrate and comprising a plurality of inorganic insulating layers stacked and a plurality of pixel driving circuits arranged in the main display area;
an organic insulating layer, located on the pixel driving circuit layer and comprising a first organic insulating sub-layer and a second organic insulating sub-layer located on the first organic insulating sub-layer; and
a light-emitting layer, located on the organic insulating layer and comprising a plurality of first pixels located in the main display area and a plurality of second pixels located in the light-transmitting display area, wherein the first pixels and the second pixels are electrically connected with the corresponding pixel driving circuits;
wherein the pixel driving circuit layer comprises a plurality of first grooves in the light-transmitting display area and located between the second pixels; the first grooves adjacent to different second pixels are communicated with each other; the first organic insulating sub-layer fills the first grooves; and a first distance from a surface of the first organic insulating sub-layer located at the first grooves away from the substrate to the substrate is less than a second distance from a surface of the first organic insulating sub-layer located in the main display area away from the substrate to the substrate.

2. The display panel according to claim 1, wherein the pixel driving circuit layer further comprises:
a plurality of protrusions disposed in the light-transmitting display area and corresponding to the second pixels, one of the plurality of protrusions being surrounded by the first grooves; a third distance from a surface of the first organic insulating sub-layer located on the protrusions away from the substrate to the substrate is greater than the first distance, and less than the second distance.

3. The display panel according to claim 1, wherein the pixel driving circuit layer further comprises:
a plurality of second grooves in the light-transmitting display area and corresponding to the second pixels, one of the second grooves being communicated with the adjacent first grooves.

4. The display panel according to claim 3, wherein a fourth distance from a surface of the first organic insulating sub-layer located at the second grooves away from the substrate to the substrate is equal to the first distance.

5. The display panel according to claim 3, wherein a depth of the first grooves is equal to a depth of the second grooves.

6. The display panel according to claim 1, wherein the first organic insulating sub-layer comprises third grooves in the light-transmitting display area and corresponding to the first grooves, and a width of the third grooves is less than or equal to a width of the first grooves.

7. The display panel according to claim 6, wherein a projection width of sidewalls of the third grooves on the substrate is less than or equal to a projection width of sidewalls of the first grooves on the substrate.

8. The display panel according to claim 1, wherein each of the first grooves comprises a plurality of sub-grooves stacked and communicated with each other, and a width of the sub-grooves away from the substrate is greater than a width of the sub-grooves adjacent to the substrate.

9. The display panel according to claim 8, wherein the plurality of the sub-grooves comprises a first sub-groove and a second sub-groove, and the pixel driving circuit layer comprises:
a buffer layer, located on the substrate;
a first gate insulating layer, located on the buffer layer;
a second gate insulating layer, located on the first gate insulating layer; and
an interlayer dielectric layer, located on the second gate insulating layer;
wherein a width of the first sub-groove formed on the buffer layer and the first gate insulating layer is less than a width of the second sub-groove formed on the second gate insulating layer and the interlayer dielectric layer.

10. The display panel according to claim 9, wherein an included angle between a bottom surface of the second sub-groove and a sidewall of the second sub-groove is less than or equal to 115 degrees.

11. The display panel according to claim 9, further comprising:
a light shielding layer located below the pixel driving circuit layer, and provided with an opening corresponding to the first groove, wherein a width of the opening is greater than or equal to the width of the first sub-groove.

12. The display panel according to claim 1, wherein the substrate comprises a base substrate and a barrier layer thereon.

13. A display device, comprising a display panel comprising a light-transmitting display area and a main display area adjacent to the light-transmitting display area, wherein a light transmittance of the light-transmitting display area is greater than a light transmittance of the main display area, and the display panel comprises:
a substrate;
a pixel driving circuit layer, located on the substrate and comprising a plurality of inorganic insulating layers stacked and a plurality of pixel driving circuits arranged in the main display area;
an organic insulating layer, located on the pixel driving circuit layer and comprising a first organic insulating sub-layer and a second organic insulating sub-layer located on the first organic insulating sub-layer; and
a light-emitting layer, located on the organic insulating layer and comprising a plurality of first pixels located in the main display area and a plurality of second pixels located in the light-transmitting display area, wherein the first pixels and the second pixels are electrically connected with the corresponding pixel driving circuits;
wherein the pixel driving circuit layer comprises a plurality of first grooves in the light-transmitting display area and located between the second pixels; the first grooves adjacent to different second pixels are communicated with each other; the first organic insulating sub-layer fills the first grooves, and a first distance from a surface of the first organic insulating sub-layer located at the first grooves away from the substrate to the substrate is less than a second distance from a surface of the first organic insulating sub-layer located in the main display area away from the substrate to the substrate.

14. The display panel according to claim 13, wherein the pixel driving circuit layer further comprises:
a plurality of protrusions disposed in the light-transmitting display area and corresponding to the second pixels, one of the plurality of protrusions being surrounded by the first grooves; a third distance from a surface of the first organic insulating sub-layer located on the protrusions away from the substrate to the substrate is greater than the first distance, and less than the second distance.

15. The display panel according to claim 13, wherein the pixel driving circuit layer further comprises:
a plurality of second grooves provided in the light-transmitting display area and corresponding to the second pixels, and the second grooves are communicated with the adjacent first grooves.

16. The display panel according to claim 15, wherein a fourth distance from a surface of the first organic insulating sub-layer located at the second grooves away from the substrate to the substrate is equal to the first distance.

17. The display panel according to claim 13, wherein the first organic insulating sub-layer comprises third grooves in the light-transmitting display area and corresponding to the first grooves, and a width of the third grooves is less than or equal to a width of the first grooves.

18. The display panel according to claim 17, wherein a projection width of sidewalls of the third grooves on the substrate is less than or equal to a projection width of sidewalls of the first grooves on the substrate.

19. The display panel according to claim 13, wherein each of the first grooves comprises a plurality of sub-grooves stacked and communicated with each other, and a width of the sub-grooves away from the substrate is greater than a width of the sub-grooves adjacent to the substrate.

20. The display panel according to claim 19, wherein the plurality of the sub-grooves comprises a first sub-groove and a second sub-groove, a width of the first sub-groove is less than a width of the second sub-groove, and an included angle between a bottom surface of the second sub-groove and a sidewall of the second sub-groove is less than or equal to 115 degrees.
